(19) United States
(12) Patent Application Publication
(10) Pub. No.: US 2018/0076201 A1
(43) Pub. Date: Mar. 15, 2018

(54) SEMICONDUCTOR DEVICE

(71) Applicant: Fuji Electric Co., Ltd., Kanagawa (JP)

(72) Inventors: Yoshiaki TOYODA, Nagano (JP); Hideaki KATAKURA, Nagano (JP)

(73) Assignee: Fuji Electric Co., Ltd., Kanagawa (JP)

(21) Appl. No.: 15/696,534

(22) Filed: Sep. 6, 2017

(30) Foreign Application Priority Data
Sep. 14, 2016 (JP) 2016-180036

(51) Int. Cl. H01L 27/092; H01L 29/423; H01L 21/762; H01L 29/36

(52) U.S. Cl. CPC H01L 27/0922; H01L 29/4236; H03F 3/45237; H01L 29/36; H01L 21/76202

(57) ABSTRACT

A semiconductor device includes a lateral MOSFET and a vertical semiconductor device that are formed on the same semiconductor substrate. In the lateral MOSFET, the voltage of a back-gate electrode is set to be higher than the voltage of a source electrode and a gate electrode by greater than or equal to a prescribed value (greater than or equal to 40V). A drain-side diffusion region, a drain diffusion region, a drain electrode, a gate insulating film, a gate electrode, and a LOCOS film are formed in annular shapes centered on a source diffusion region. As a result, an active channel region between the drain diffusion region and the source diffusion region as well as peripheral portions of the LOCOS film are also annular-shaped.

### BACKGROUND OF THE INVENTION

### Technical Field

The present invention relates to a semiconductor device.

### Background Art

Power integrated circuits (power ICs) in which both a vertical power semiconductor device and a lateral power semiconductor device for controlling/providing a protection circuit for the vertical power semiconductor device are mounted on the same semiconductor substrate (semiconductor chip) are a well-known conventional technology for increasing the reliability and reducing the size and cost of power semiconductor devices (see Patent Documents 1 and 2 and Non-Patent Document 1, for example).

When such a power IC is a high-side power IC for a vehicle, for example, an output stage vertical n-channel metal-oxide-semiconductor field-effect transistor (MOSFET) as well as a lateral MOSFET for controlling this n-channel MOSFET are formed on an n-type semiconductor substrate. The drain terminal of this vertical n-channel MOSFET is formed on one of the principal surface sides of the n-type semiconductor substrate and is connected to a battery power supply for the vehicle, which typically has a voltage of approximately 12V. However, due to the possibility of malfunctions, it must be assumed that higher voltages may also potentially be applied. Here, “higher voltages” refers to voltages of greater than or equal to approximately 40V or 60V. The drain terminal of the vertical n-channel MOSFET also functions as the back-gate terminal of a lateral p-channel MOSFET, for example, and therefore these higher voltages are also applied to this back-gate terminal of the lateral p-channel MOSFET. Next, a lateral p-channel MOSFET mounted in a power IC will be described with reference to FIGS. 8A and 8B.

FIGS. 8A and 8B are explanatory drawings illustrating an example of the structure of a lateral p-channel MOSFET mounted in a conventional power IC. FIG. 8A is a cross-sectional view of the structure of a lateral p-channel MOSFET 800. FIG. 8B is a plan view of the structure of the lateral p-channel MOSFET 800. FIG. 8A illustrates a cross section taken along line B-B′ in FIG. 8B. As illustrated in FIG. 8A, the Z-axis direction is the depth direction of the cross-sectional structure of the lateral p-channel MOSFET 800. Moreover, the X-axis direction is the lateral direction of the cross-sectional structure of the lateral p-channel MOSFET 800. As illustrated in FIG. 8B, the Y-axis direction is the direction going into the page relative to the cross-sectional structure of the lateral p-channel MOSFET 800.

Here, a semiconductor substrate 120 is formed by epitaxially growing an n⁻ epitaxial layer 102 on one principal surface of an n⁺ supporting substrate 101. A drain-side p⁻ diffusion region 103 and a source-side p⁻ diffusion region 104 are selectively formed separated from one another in the surface layer of the front surface of the semiconductor substrate 120 (that is, on the side of the n⁻ epitaxial layer 102 opposite to the n⁺ supporting substrate 101).

Moreover, a p⁺ drain diffusion region 105 is selectively formed in the surface layer of the drain-side p⁻ diffusion region 103. A drain electrode 109 is formed contacting the surface of the p⁺ drain diffusion region 105. A p⁺ source diffusion region 106 is selectively formed in the surface layer of the source-side p⁻ diffusion region 104. A source electrode 110 is formed contacting the surface of the p⁺ source diffusion region 106.

Furthermore, a gate electrode 108 made of polysilicon (poly-Si) is formed on the surface of a portion of the epitaxial layer 102 that is positioned between the source-side p⁻ diffusion region 104 and the drain-side p⁻ diffusion region 103.

The impurity concentrations of the drain-side p⁻ diffusion region 103 and the source-side p⁻ diffusion region 104 are set such that the source-drain withstand voltage (hereinafter, the “lateral withstand voltage”) is greater than or equal to the required withstand voltage for the power IC for the vehicle. Here, the required withstand voltage is approximately 40V to 60V, for example.

An n⁺ back-gate diffusion region 117 is selectively formed separated from the p⁻ diffusion region 103 and the diffusion region 104 in the surface layer of the front surface of the semiconductor substrate 120. A back-gate electrode 115 is formed contacting the surface of the n⁺ back-gate diffusion region 117.

Moreover, a local oxidation of silicon (LOCOS) film (a thick insulating film) 111 is selectively formed on the front surface of the semiconductor substrate 120. The LOCOS film 111 is selectively formed on the front surface of the semiconductor substrate 120 in order to electrically isolate the lateral p-channel MOSFET 800 formed on the semiconductor substrate 120 from other devices, for example. The LOCOS film 111 is formed on the surface of the drain-side p⁻ diffusion region 103 on a portion of the region other than the drain diffusion region 105 that is positioned on the side opposite to the source-side p⁻ diffusion region 104 in the X-axis direction, for example. The LOCOS film 111 is also formed on the surface of the semiconductor substrate 120 on a portion other than the n⁺ back-gate diffusion region 117 that is positioned on the side of the n⁺ back-gate diffusion region 117 opposite to the source-side p⁻ diffusion region 104 in the X-axis direction. In this way, the device is electrically isolated.

Moreover, the LOCOS film 111 is also formed between the back-gate diffusion region 117 and the source diffusion region 106 in order to electrically isolate the back-gate diffusion region 117 and the source diffusion region 106 from one another. Furthermore, in order to make it possible to achieve a prescribed lateral withstand voltage, the LOCOS film 111 is also selectively formed on the region of the surface of the drain-side p⁻ diffusion region 103 other than the drain diffusion region 105 on a portion that is positioned on the source-side p⁻ diffusion region 104 side in the X-axis direction, for example.

In FIG. 8B, the portions indicated by the dashed rectangles are the edges of the LOCOS film 111. In the LOCOS film 111, portions such as the portion formed to improve the lateral withstand voltage and the portion formed to electrically isolate the source diffusion region 106 and the back-gate diffusion region 117 from one another are connected in the Y-axis direction to the portions for isolating the device, for example. Therefore, the length of the channel (hereinafter, the “channel length”) that forms in the p-channel MOSFET 800 when in the ON state is equal to the length of the region (hereinafter, the “active channel region”) between the source-side p⁻ diffusion region 104 and the drain-side p⁻ diffusion region 103 in the X-axis direction.

A back-gate terminal 116 of the back-gate electrode 115 is subjected to the same voltages as a substrate electrode 118 of the n-type semiconductor substrate 120, and therefore high voltages can potentially be applied to this back-gate terminal 116 of the back-gate electrode 115. Here, the region of the n⁻ epitaxial layer 102 other than the drain-side p⁻ diffusion region 103 and the source-side p⁻ diffusion region 104 will also be referred to as a “drift region.” The drift region experiences the same voltages as the back-gate electrode 115 and the substrate electrode 118 and can therefore potentially have high voltages applied thereto. Moreover, components such as the drift region, the semiconductor supporting substrate 101, and the substrate electrode 118 will also be collectively referred to as a “back gate.” The p-n junction between the drift region and the source-side p⁻ diffusion region 104 will also be referred to as a “vertical p-n junction.” Furthermore, the withstand voltage of this vertical p-n junction will also be referred to simply as the “vertical withstand voltage” or the “source-back gate withstand voltage.”

In a conventional lateral p-channel MOSFET, an n⁺ diffusion region and a source diffusion region formed on the front surface of a back-gate semiconductor substrate are connected via metal wiring, and therefore the source terminal of the source electrode and the back-gate terminal of the back-gate electrode experience the same voltages. However, when a vertical n-channel MOSFET is formed in the same substrate as the lateral p-channel MOSFET 800, for example, the n⁺ diffusion region 117 and the p⁺ source diffusion region 106 are not connected via metal wiring, and therefore a source terminal 114 and the back-gate terminal 116 sometimes experience different voltages. For example, sometimes a high voltage is applied to the back-gate terminal 116 while a low voltage is applied to the source terminal 114 in the p-channel MOSFET 800.

In such cases, the vertical p-n junction gets reverse-biased, and therefore if a voltage higher than the designed withstand voltage of the vertical p-n junction actually gets applied between the source and the back gate, the vertical p-n junction will typically undergo reverse breakdown. Therefore, the designed withstand voltage of the vertical p-n junction must be higher than the voltages that will actually be applied between the source and the back gate. As illustrated in FIG. 8A, the source-side p⁻ diffusion region 104 is formed in order to make it possible to achieve a prescribed vertical withstand voltage, for example.

Moreover, in some cases the source-side p⁻ diffusion region 104 and the drain-side p⁻ diffusion region 103 are formed as part of the same process in order to reduce the number of manufacturing steps for the lateral p-channel MOSFET, for example. In such cases, the withstand voltage of the vertical p-n junction is approximately equal to the source-drain withstand voltage.

Furthermore, in the field of lateral power MOSFETs and lateral diodes, device structures in which no ends of the active channel region are formed in the width direction of the active channel region are conventionally well-known (see Patent Documents 3 to 7, for example). For example, Patent Documents 5 and 6 disclose bidirectional trench lateral power MOSFET (TLPM) structures in which a trench or the like is formed in an annular shape as examples of device structures in which no ends are formed in the active channel region.

Patent Document 4 describes efficiently eliminating residual carriers by avoiding forming ends in a lateral diode, for example. Moreover, Patent Document 5 describes increasing reliability by avoiding forming ends in a TLPM, for example. Furthermore, Patent Document 6 describes reducing on-resistance or keeping on-resistance constant while increasing withstand voltage by avoiding forming ends in a lateral power MOSFET, for example. In addition, Patent Document 7 describes achieving high withstand voltage performance without increasing on-voltage by avoiding forming ends in a lateral power MOSFET, for example.

### RELATED ART DOCUMENTS

### Patent Documents

Patent Document 1: Japanese Patent No. 3413569

Patent Document 2: Japanese Patent No. 5410055

Patent Document 3: WO 2003/075353

Patent Document 4: Japanese Patent Application Laid-Open Publication No. 2015-90952

Patent Document 5: Japanese Patent No. 5070751

Patent Document 6: Japanese Patent No. 5157164

Patent Document 7: Japanese Patent No. 3647802

### Non-Patent Document

Non-Patent Document 1: Shin KIUCHI, Minoru NISHIO, Takanori KOHAMA, “Automotive Smart MOSFETs,” Fuji Electric Journal, Vol.76 No. 10, 2003

### SUMMARY OF THE INVENTION

In a lateral p-channel MOSFET (see FIGS. 8A and 8B) mounted in a conventional power IC of the type described above, the voltages of the source terminal 114 and a gate terminal 112 are sometimes lower than the supply voltage. This creates several restrictions to the usage of the device: any decrease in the current drive capability of the lateral p-channel MOSFET resulting from applying the supply voltage to the back-gate terminal 116 must be accepted, and a voltage that is low enough that the voltage between the source and the back gate becomes less than the designed withstand voltage of the vertical p-n junction must be applied to the source terminal 114.

Moreover, as described above, when the lateral p-channel MOSFET is mounted in a power IC for a vehicle, the back-gate terminal 116 is connected to a battery power supply, and therefore the vertical p-n junction must have a high withstand voltage (that is, higher than the battery voltage) of greater than or equal to approximately 40V or 60V in order to account for the possibility of surge voltages being input.

However, the vertical p-n junction sometimes undergoes breakdown at a voltage lower than the designed withstand voltage. The reason why the vertical p-n junction sometimes undergoes breakdown at a voltage lower than the designed withstand voltage will be described with reference to FIGS. 9A and 9B.

FIGS. 9A and 9B are explanatory drawings illustrating an example of a location at which an electric field concentrates in the lateral p-channel MOSFET mounted in the conventional power IC. In FIGS. 9A and 9B, the location in the lateral p-channel MOSFET 800 at which the electric field concentrates is indicated by the x symbol. FIG. 9B is a plan view of the structure of the lateral p-channel MOSFET 800. FIG. 9A is a cross-sectional view of the structure of the lateral p-channel MOSFET and illustrates a cross section taken along line B-B′ in FIG. 9B. Note that while the cross-sectional structure illustrated in FIG. 9A is the same as the cross-sectional structure illustrated in FIG. 8A, FIG. 9A further illustrates the voltages applied to each terminal of the p-channel MOSFET 800 as well as the location at which the electric field concentrates.

As illustrated in FIG. 9A, the gate terminal 112, the drain terminal 113, and the source terminal 114 are each grounded or have a low voltage applied thereto. Moreover, the back-gate terminal 116 and the semiconductor substrate 120 are connected to the battery power supply. The edge of the LOCOS film 111 is positioned near the end of the active channel region in the p-channel MOSFET in the Y-axis direction (the location indicated by the x symbol), and therefore when the gate terminal 112 and the source terminal 114 have a low voltage and the semiconductor substrate 120 has a high voltage, the resulting electric field concentrates near this end. Therefore, the vertical p-n junction near this end undergoes breakdown at a voltage lower than the designed source-drain withstand voltage.

Moreover, when the source terminal 114 and the gate terminal 112 are biased to a low voltage, the withstand voltage of the lateral p-channel MOSFET 800 in the vertical direction (the Z-axis direction) depends on the channel length L (see FIGS. 8A and 8B). This is so because the curvature of the p⁻ diffusion region 104 and the p⁻ diffusion region 103 reduces the vertical withstand voltage of the lateral p-channel MOSFET 800, and the greater the channel length L is, the more the effect of this curvature reduces the vertical withstand voltage (see FIG. 7 (described later)). Therefore, when the source terminal 114 and the gate terminal 112 are biased to a low voltage and the back-gate terminal 116 is biased to a high voltage, the withstand voltage margin relative to the required vertical withstand voltage of the lateral p-channel MOSFET 800 decreases, and in order to secure the withstand voltage margin, the channel length L cannot be increased to any appreciable extent. Thus, when the source terminal 114 and the gate terminal 112 are biased to a low voltage and the back-gate terminal 116 is biased to a high voltage, the withstand voltage of the vertical p-n junction decreases.

The present invention aims to provide a semiconductor device that makes it possible to improve the withstand voltage of the vertical p-n junction in a lateral semiconductor device. Accordingly, the present invention is directed to a scheme that substantially obviates one or more of the problems due to limitations and disadvantages of the related art.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device having a lateral semiconductor device and a vertical semiconductor device formed on a semiconductor substrate of a first conductivity type, wherein the lateral semiconductor device includes: a first diffusion region of a second conductivity type selectively formed in a surface layer of one principal surface of the semiconductor substrate; a second diffusion region of the second conductivity type selectively formed separated from the first diffusion region in the surface layer of the one principal surface of the semiconductor substrate; a third diffusion region of the second conductivity type selectively formed within the first diffusion region and at a higher impurity concentration than the first diffusion region; a fourth diffusion region of the second conductivity type selectively formed within the second diffusion region and at a higher impurity concentration than the second diffusion region; a local insulating film selectively formed around a periphery of the lateral semiconductor device on the one principal surface of the semiconductor substrate, and also selectively formed on a portion of the one principal surface of the semiconductor substrate positioned between the third diffusion region and the fourth diffusion region; and a gate electrode formed on at least a portion of the one principal surface of the semiconductor substrate positioned between the first diffusion region and the second diffusion region, with a gate insulating film interposed therebetween, the gate electrode also being formed on a portion of a surface of the local insulating film with the gate insulating film interposed therebetween, wherein the semiconductor device is configured to receive a voltage on another principal surface of the semiconductor substrate that is set to be higher than voltages of the gate electrode, the third diffusion region, and the fourth diffusion region by greater than or equal to a prescribed value, and wherein the first diffusion region, the third diffusion region, the gate electrode, and the local insulating film are formed in annular shapes surrounding the fourth diffusion region in a planar pattern.

In the semiconductor device according to one aspect of the present invention as described above, the third diffusion region may be a drain diffusion region, the fourth diffusion region may be a source diffusion region, and, on the portion of the one principal surface of the semiconductor substrate positioned between the third diffusion region and the fourth diffusion region, the local insulating film may be selectively formed on a portion of the first diffusion region other than where the third diffusion region is formed.

In the semiconductor device according to one aspect of the present invention as described above, the third diffusion region may be a source diffusion region, the fourth diffusion region may be a drain diffusion region, and, on the portion of the one principal surface of the semiconductor substrate positioned between the third diffusion region and the fourth diffusion region, the local insulating film may be selectively formed on a portion of the second diffusion region other than where the fourth diffusion region is formed.

In the semiconductor device according to one aspect of the present invention as described above, on the portion of the one principal surface of the semiconductor substrate positioned between the third diffusion region and the fourth diffusion region, the local insulating film may be selectively formed on a portion of the first diffusion region other than where the third diffusion region is formed, and may be also selectively formed on a portion of the second diffusion region other than where the fourth diffusion region is formed; the gate electrode may be formed to cover at least a portion of a surface of the local insulating film that is selectively formed on the portion of the first diffusion region and a portion of a surface of the local insulating film that is selectively formed on the portion of the second diffusion region; and the third diffusion region, the gate electrode, and the local insulating film may be formed symmetrically about the fourth diffusion region in a planar pattern.

In the semiconductor device according to one aspect of the present invention as described above, the lateral semiconductor device may further include: a fifth diffusion region of the first conductivity type selectively formed in the surface layer of the one principal surface of the semiconductor substrate, the fifth diffusion region being separated from the first diffusion region and the second diffusion region; and a back-gate electrode contacting the fifth diffusion region, and the second diffusion region and the fourth diffusion region may be formed in annular shapes surrounding the fifth diffusion region in a planar pattern.

In the semiconductor device according to one aspect of the present invention as described above, the first conductivity type may be n-type and the second conductivity type may be p-type.

In the semiconductor device according to one aspect of the present invention as described above, the prescribed value may be greater than or equal to 40V.

In one aspect, the present disclosure provides an operational amplifier, including: an input differential stage; a p-channel MOSFET connected to the input differential stage; and an n-channel MOSFET connected to the input differential stage, wherein the input differential stage includes a lateral p-type MOSFET device that includes: a first diffusion region of p-type selectively formed in a surface layer of one principal surface of a semiconductor substrate of n-type; a second diffusion region of p-type selectively formed separated from the first diffusion region in the surface layer of the one principal surface of the semiconductor substrate; a third diffusion region of p-type selectively formed within the first diffusion region and at a higher impurity concentration than the first diffusion region; a fourth diffusion region of p-type selectively formed within the second diffusion region and at a higher impurity concentration than the second diffusion region; a local insulating film selectively formed around a periphery of the lateral semiconductor device on the one principal surface of the semiconductor substrate, and also selectively formed on a portion of the one principal surface of the semiconductor substrate positioned between the third diffusion region and the fourth diffusion region; and a gate electrode formed on at least a portion of the one principal surface of the semiconductor substrate positioned between the first diffusion region and the second diffusion region, with a gate insulating film interposed therebetween, the gate electrode also being formed on a portion of a surface of the local insulating film with the gate insulating film interposed therebetween, wherein the operational amplifier is configured such that another principal surface of the semiconductor substrate of the lateral p-type MOSFET device receives a voltage that is set to be higher than voltages of the gate electrode, the third diffusion region, and the fourth diffusion region by greater than or equal to a prescribed value, and wherein the first diffusion region, the third diffusion region, the gate electrode, and the local insulating film are formed in annular shapes surrounding the fourth diffusion region in a planar pattern.

A semiconductor device according to the present invention makes it possible to improve the withstand voltage of the vertical p-n junction in a lateral semiconductor device. It is to be understood that both the foregoing general description and the following detailed description are exemplary and explanatory, and are intended to provide further explanation of the invention as claimed.

### BRIEF DESCRIPTION OF THE DRAWINGS

FIGS. 1A and 1B are explanatory drawings illustrating an example of the structure of a lateral power MOSFET according to Embodiment 1.

FIG. 2 is an explanatory drawing illustrating an example of an input differential stage of an op-amp that uses a lateral power MOSFET.

FIGS. 3A and 3B are explanatory drawings illustrating an example of the structure of a lateral power MOSFET according to Embodiment 2.

FIGS. 4A and 4B are explanatory drawings illustrating an example of the structure of a lateral power MOSFET according to Embodiment 3.

FIGS. 5A and 5B are explanatory drawings illustrating an example of the structure of a lateral power MOSFET according to Embodiment 4.

FIG. 6 is a cross-sectional view illustrating the structure of a semiconductor device according to an embodiment.

FIG. 7 is an explanatory drawing illustrating the relationship between channel length L and vertical withstand voltage in a semiconductor device according to an embodiment and in a conventional semiconductor device.

FIGS. 8A and 8B are explanatory drawings illustrating an example of the structure of a lateral p-channel MOSFET mounted in a conventional power IC.

FIGS. 9A and 9B are explanatory drawings illustrating an example of a location at which an electric field concentrates in the lateral p-channel MOSFET mounted in the conventional power IC.

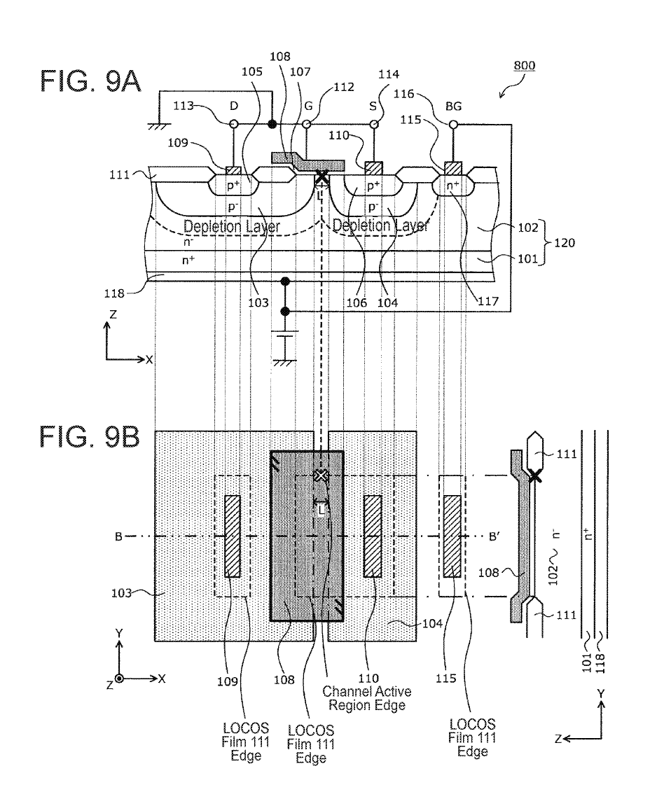

### DETAILED DESCRIPTION OF EMBODIMENTS

Embodiments of a semiconductor device according to the present invention will be described in detail below with reference to the attached drawings. In the present specification and the attached drawings, the letters “n” and “p” are used to indicate whether the majority carriers in a layer or region are electrons or holes, respectively. Moreover, the symbols + and − are appended to the letters n and p to indicate layers or regions having a higher or lower impurity concentration, respectively, than layers or regions in which the + and − symbols are not appended. In the descriptions of the embodiments and the attached drawings, the same reference characters are used to indicate components that are the same, and redundant descriptions of such components will be omitted.

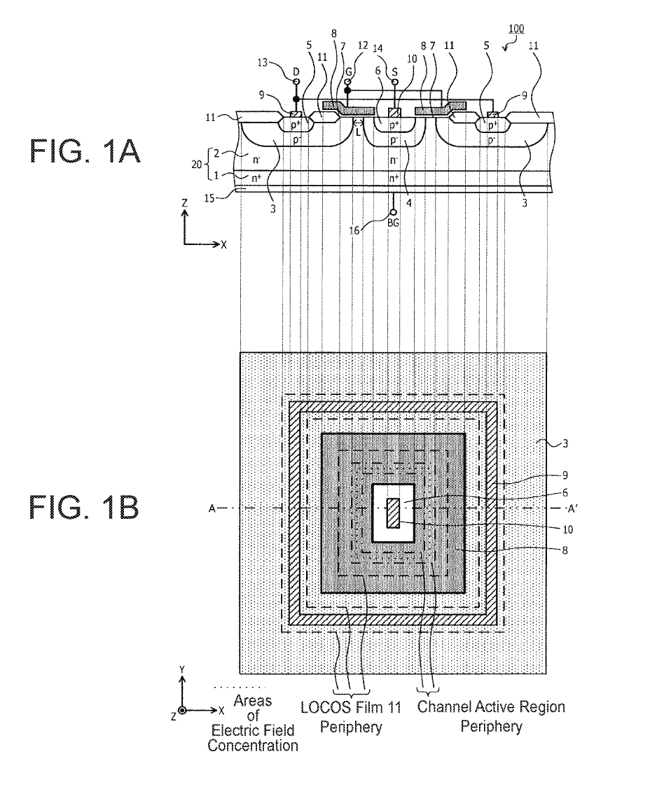

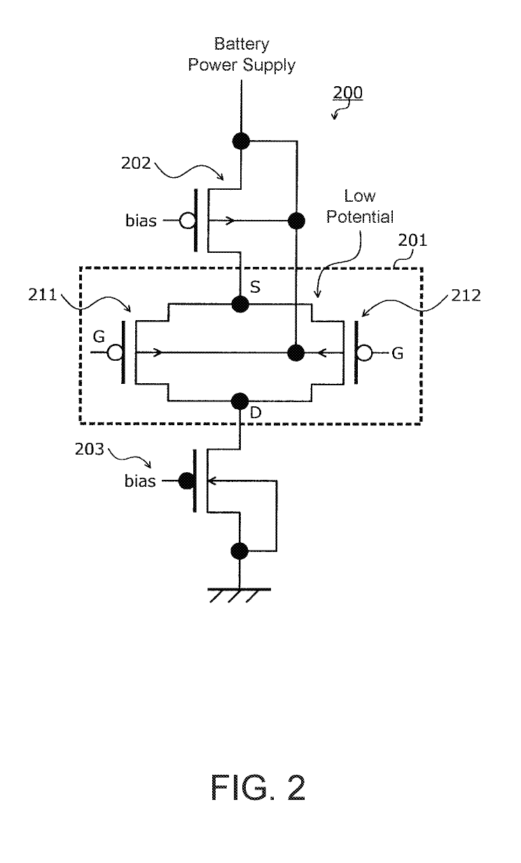

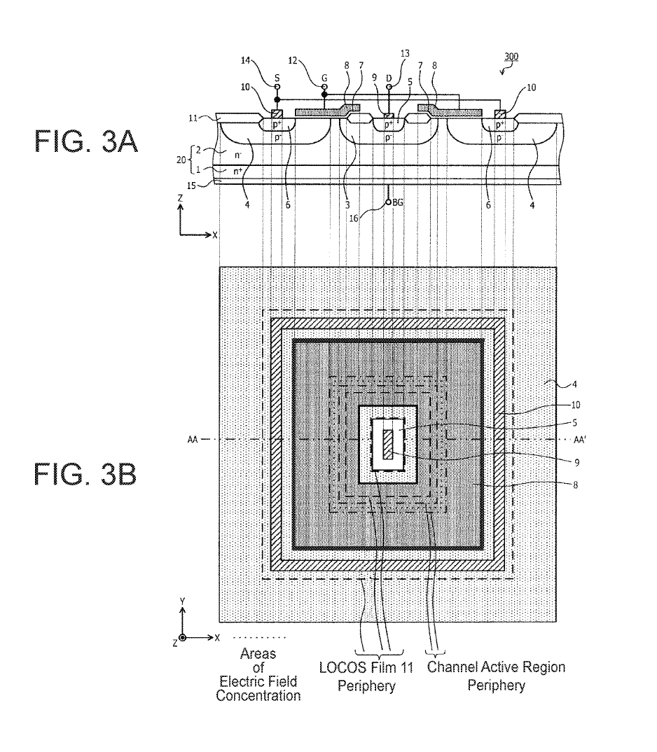

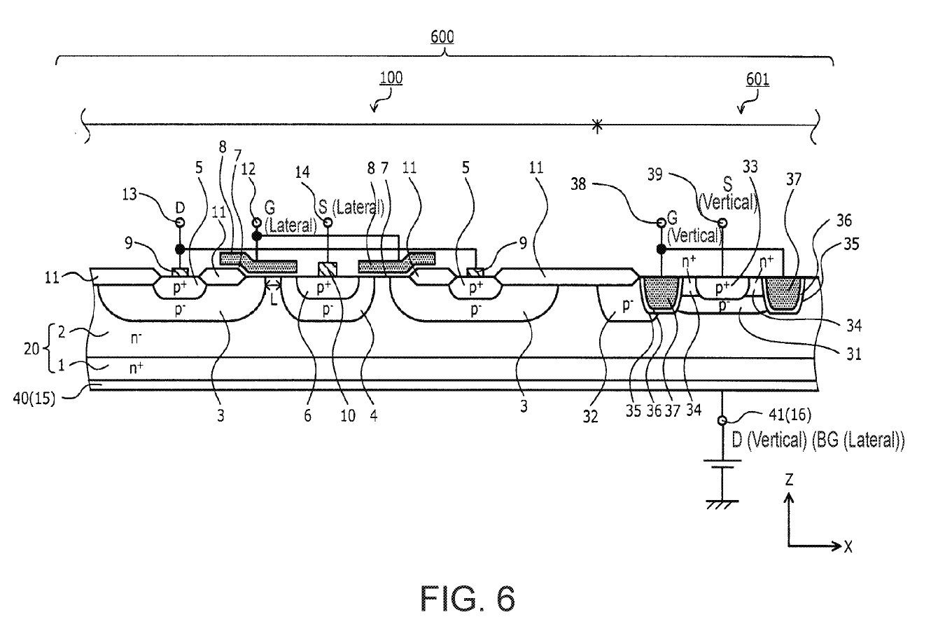

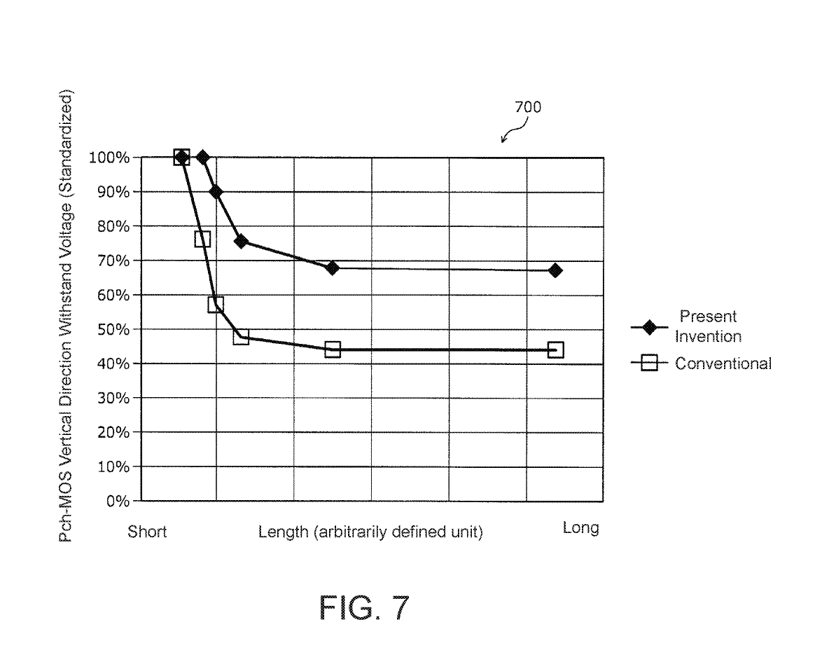

FIGS. 1A & 1B and FIGS. 3A & 3B to 5A & 5B respectively illustrate examples of different structures for a lateral power MOSFET according to Embodiments 1 to 4 of the present invention. Moreover, FIG. 2 illustrates an example of an input differential stage of an op-amp (operational amplifier) that uses the lateral power MOSFET according to an embodiment. Furthermore, FIG. 6 illustrates an example in which the lateral power MOSFET according to an embodiment and a vertical power MOSFET are mounted on the same semiconductor substrate. FIG. 7 illustrates the relationship between channel length and vertical withstand voltage in a lateral power MOSFET for a conventional lateral power MOSFET and for the lateral power MOSFET according to an embodiment.

### Embodiment 1

FIGS. 1A and 1B are explanatory drawings illustrating an example of the structure of a lateral power MOSFET according to Embodiment 1. FIG. 1A is a cross-sectional view of the structure of a lateral p-channel MOSFET 100. FIG. 1B is a plan view of the structure of the lateral p-channel MOSFET 100. FIG. 1A illustrates a cross section taken along line A-A′ in FIG. 1B. As described above in Background Art, the X-axis direction is the lateral direction of the cross-sectional structure of the lateral p-channel MOSFET 100, the Z-axis direction is the depth direction of the cross-sectional structure of the lateral p-channel MOSFET 100, and the Y-axis direction is the direction going into the page relative to the cross-sectional structure of the lateral p-channel MOSFET 100. A semiconductor substrate 20 includes the p-channel MOSFET 100 as well as a vertical semiconductor device (not illustrated in the figure).

The semiconductor substrate 20 is formed by epitaxially growing an epitaxial layer 2 of a first conductivity type on one principal surface of a supporting substrate 1 of the first conductivity type. The present embodiment is described using the p-channel MOSFET 100 as an example, and therefore the first conductivity type is n-type and a second conductivity type is p-type.

A drain-side p⁻ diffusion region 3 and a source-side p⁻ diffusion region 4 are selectively formed separated from one another in the surface layer of the front surface of the semiconductor substrate 20 (that is, on the side of the n⁻ epitaxial layer 2 opposite to the n⁺ supporting substrate 1). In Embodiment 1, the drain-side p⁻ diffusion region 3 corresponds to a first diffusion region of the second conductivity type, and the source-side p⁻ diffusion region 4 corresponds to a second diffusion region of the second conductivity type. The impurity concentrations of the drain-side p⁻ diffusion region 3 and the source-side p⁻ diffusion region 4 are respectively less than the impurity concentrations of a p⁺ drain diffusion region 5 and a p⁺ source diffusion region 6 (described below).

The p⁺ drain diffusion region 5 is selectively formed in the surface layer of the drain-side p⁻ diffusion region 3 on the front surface side of the semiconductor substrate 20. The p⁺ source diffusion region 6 is selectively formed in the surface layer of the source-side p⁻ diffusion region 4 on the front surface side of the semiconductor substrate 20. In Embodiment 1, the p⁺ drain diffusion region 5 corresponds to a third diffusion region, and the p⁺ source diffusion region 6 corresponds to a fourth diffusion region. The impurity concentration of the p⁺ drain diffusion region 5 is greater than the impurity concentration of the drain-side p⁻ diffusion region 3. The impurity concentration of the p⁺ source diffusion region 6 is greater than the impurity concentration of the source-side p⁻ diffusion region 4.

Here, similar to in the Background Art, the region of the n⁻ epitaxial layer 2 other than the drain-side p⁻ diffusion region 3 and the source-side p⁻ diffusion region 4 will be referred to as a “drift region.” Moreover, similar to in the Background Art, the p-n junction between the drift region and the source-side p⁻ diffusion region 4 will also be referred to as a “vertical p-n junction.” Furthermore, the withstand voltage of this vertical p-n junction will also be referred to as the “vertical withstand voltage.”

A drain electrode 9 is formed on the surface of the p⁺ drain diffusion region 5 on the front surface side of the semiconductor substrate 20. Voltages are applied to the p⁺ drain diffusion region 5 via a drain terminal 13 of the drain electrode 9. A source electrode 10 is formed on the surface of the p⁺ source diffusion region 6 on the front surface side of the semiconductor substrate 20. Voltages are applied to the p⁺ source diffusion region 6 via a source terminal 14 of the source electrode 10.

Moreover, a LOCOS film (a thick insulating film; a local insulating film) 11 is formed around the periphery of the p-channel MOSFET 100 in order to provide electrical isolation between devices on the front surface of the semiconductor substrate 20. As illustrated in FIG. 1A, the LOCOS film 11 is formed on a portion other than the p⁺ drain diffusion region 5 of the area corresponding to the drain-side p⁻ diffusion region 3 on the front surface of the semiconductor substrate 20, this portion being positioned on the side opposite to the source-side p⁻ diffusion region 4 in the X-axis direction, for example.

The LOCOS film 11 is also selectively formed on a portion of the front surface of the semiconductor substrate 20 other than the source-side p⁻ diffusion region 4 and the p⁺ drain diffusion region 5 in order to improve the lateral withstand voltage. More specifically, the LOCOS film 11 is selectively formed on a portion other than the p⁺ drain diffusion region 5 of the area corresponding to the drain-side p⁻ diffusion region 3 on the front surface of the semiconductor substrate 20, this portion being positioned on the source-side p⁻ diffusion region 4 side in the X-axis direction. Moreover, in the example structure according to Embodiment 1 as illustrated in FIGS. 1A and 1B, the LOCOS film 11 does not necessarily need to be formed on the surface of the source-side p⁻ diffusion region 4 on the front surface of the semiconductor substrate 20.

A gate electrode 8 made of polysilicon (poly-Si) is selectively formed on the front surface of the semiconductor substrate 20 with a gate insulating film 7 interposed therebetween. More specifically, the gate electrode 8 is formed on the surface of a portion of the epitaxial layer 2 that is positioned between the source-side p⁻ diffusion region 4 and the p⁺ drain diffusion region 5, with the gate insulating film 7 interposed therebetween.

Here, the drain-side edges of the gate electrode 8 are not terminated at locations at which the electric field concentrates, such as near the periphery of the LOCOS film 11. Thus, the gate electrode 8 is formed such that the drain-side periphery thereof is arranged above the LOCOS film 11 that is formed on the portion of the area of the drain-side p⁻ diffusion region 3 on the front surface of the semiconductor substrate 20 that is positioned on the source-side p⁻ diffusion region 4 side, with the gate insulating film 7 interposed therebetween. Moreover, voltages are applied to the gate electrode 8 via a gate terminal 12.

In addition, in the p-channel MOSFET 100, a prescribed lateral withstand voltage is achieved by using a structure having the following three characteristics, for example, to reduce the strength of the electric field beneath the gate electrode 8 (that is, in the portion that faces the gate electrode 8 with the semiconductor substrate 20 and the gate insulating film 7 sandwiched therebetween). First, the LOCOS film 11 is formed on the portion other than the p⁺ drain diffusion region 5 of the surface of the drain-side p⁻ diffusion region 3, this portion being arranged between the p⁺ drain diffusion region 5 and the p⁺ source diffusion region 6 in the X-axis direction. Second, the drain-side p⁻ diffusion region 3 is formed surrounding the p⁺ drain diffusion region 5. Third, the gate electrode 8 is formed above the LOCOS film 11 such that the drain-side edge of the gate electrode 8 is arranged on the LOCOS film 11. These three characteristics expand the equipotential lines beneath the gate electrode 8 in the lateral direction, thereby reducing electric field concentration. Therefore, in the p-channel MOSFET 100, these three characteristics make it possible to improve the lateral withstand voltage and to achieve a prescribed lateral withstand voltage.

A back-gate electrode 15 is formed on the rear surface of the semiconductor substrate 20 (that is, on the side of the n⁺type supporting substrate 1 opposite to the N⁻ type epitaxial layer 2). Voltages are applied to the semiconductor substrate 20 via a back-gate terminal 16 of the back-gate electrode 15.

Moreover, as illustrated in FIG. 1A, the drain-side p⁻ diffusion region 3, the p⁺ drain diffusion region 5, the drain electrode 9, the gate oxide film 7, the gate electrode 8, and the LOCOS film 11 are each formed symmetrically about the source-side p⁻ diffusion region 4 in the X-axis direction. Furthermore, as illustrated in FIG. 1B, the drain-side p⁻ diffusion region 3, the p⁺ drain diffusion region 5, the drain electrode 9, the gate insulating film 7, the gate electrode 8, and the LOCOS film 11 are formed in annular shapes that are centered on the p⁺ source diffusion region 6 in a planar pattern.

Here “annular shapes” refers to any closed curve shape that has no discontinuous ends when circumnavigated, for example. Examples of such annular shapes are not limited to closed quadrilateral shapes in which smaller quadrilaterals are arranged within larger quadrilaterals such as in the example illustrated in FIG. 1B, but also include closed circular shapes in which smaller circles are arranged within larger circles, running track-shaped closed shapes, and the like. In comparison with quadrilateral shapes and running track-shaped closed shapes, circular shapes have no corners corresponding to those of quadrilaterals and are also highly symmetrical, thereby making it possible to distribute the electric field more uniformly within the active channel region.

As illustrated in FIG. 1B, the source electrode 10 extends in a straight line shape in a planar pattern. Moreover, the p⁺ source diffusion region 6 and the source-side p⁻ diffusion region 4 (not illustrated in the figure) are substantially quadrilateral in a planar pattern. The gate electrode 8 and the gate insulating film 7 have closed planar shapes and are formed so as to surround the p⁺ source diffusion region 6 in a planar pattern. Although not explicitly illustrated in the figure, each portion of the LOCOS film 11 also has a closed planar shape in a planar pattern. Furthermore, the drain electrode 9 also has a closed planar shape and is formed so as to surround the gate electrode 8 in a planar pattern. Similarly, the p⁺ drain diffusion region 5 and the drain-side p⁻ diffusion region 3 (not illustrated in the figure) have closed planar shapes and are formed so as to surround the p⁺ drain diffusion region 6 and the source-side p⁻ diffusion region 4.

In the p-channel MOSFET 100, the active channel region is the region of the front surface of the semiconductor substrate 20 that is positioned between the source-side p⁻ diffusion region 4 and the drain-side p⁻ diffusion region 3 in the X-axis direction. The channel length L of this active channel region is equal to the distance from the edge of the source-side p⁻ diffusion region 4 on the drain-side p⁻ diffusion region 3 side on the front surface of the semiconductor substrate 20 to the edge of the drain-side p⁻ diffusion region 3 on the source-side p⁻ diffusion region 4 side on the front surface of the semiconductor substrate 20.

In FIG. 1B, the peripheral portions of the LOCOS film 11 are indicated by the dashed lines of a different style than the dashed lines used to indicate the locations at which the electric field concentrates. In this plan view, the outermost dashed line among the dashed lines that indicate the peripheral portions of the LOCOS film 11 indicates the drain electrode 9-side edge of the LOCOS film 11 that is formed on the portion of the drain-side p⁻ diffusion region 3 positioned on the side opposite to the gate electrode 8 in the X-axis direction. Moreover, in this plan view, the center dashed line among the dashed lines that indicate the peripheral portions of the LOCOS film 11 indicates the drain electrode 9-side edge of the LOCOS film 11 that is formed on the portion of the drain-side p⁻ diffusion region 3 positioned on the gate electrode 8 side in the X-axis direction. Furthermore, in this plan view, the innermost dashed line among the dashed lines that indicate the peripheral portions of the LOCOS film 11 indicates the edge, on the side opposite to the drain electrode 9, of the LOCOS film 11 that is formed on the portion of the drain-side p⁻ diffusion region 3 positioned on the gate electrode 8 side in the X-axis direction.

The active channel region sandwiched between the drain-side p⁻ diffusion region 3 and the source-side p⁻ diffusion region 4 has a closed planar shape in a planar pattern. Moreover, the peripheral portion of the LOCOS film 11 that is formed beneath the gate electrode 8 is disposed at a position separated from the active channel region, and this peripheral portion of the LOCOS film 11 has an annular shape in a planar pattern.

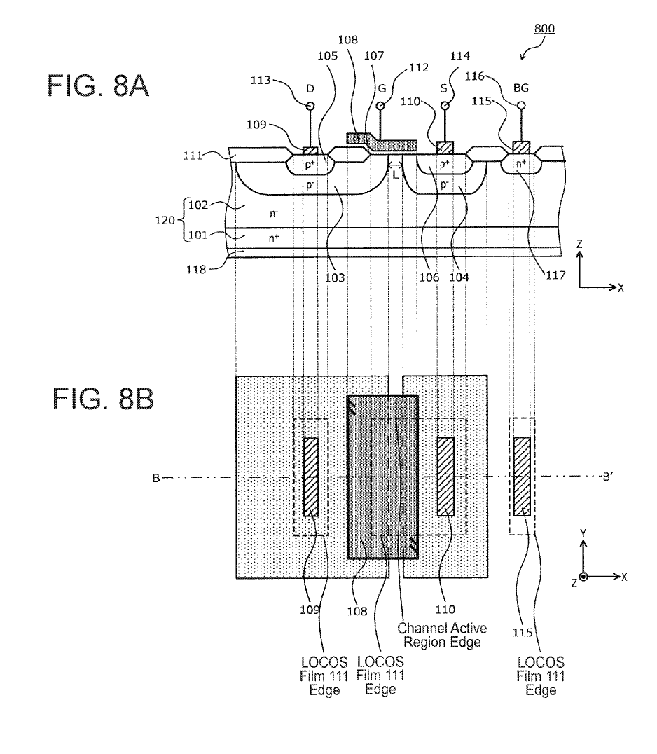

Therefore, unlike in conventional technologies, no edges of the LOCOS film 11 are present in the active channel region; thus, when the voltage of the back-gate terminal 16 becomes higher than the voltage of the gate terminal 12 and the source terminal 14 by greater than or equal to a prescribed value, the resulting electric field concentrates along the center line of the active channel region, as indicated by the dotted line in the active channel region. Here, this prescribed value is greater than or equal to 40V or 60V when the semiconductor device is for use in a vehicle, for example. Thus, the location at which the electric field concentrates is distributed over the active channel region, and the electric field does not concentrate at the ends of the active channel region in the Y-axis direction as in the conventional technology illustrated in FIGS. 8A & 8B and 9A & 9B. This makes it possible to improve the vertical withstand voltage. Moreover, as illustrated in FIG. 7 (described later), this also makes it possible to reduce any decreases in the vertical withstand voltage relative to the designed withstand voltage (greater than or equal to approximately 40V or 60V) resulting from increasing the channel length L.

FIG. 2 is an explanatory drawing illustrating an example of an input differential stage of an op-amp that uses a lateral power MOSFET. The lateral power MOSFET according to the present embodiment may be used for both of two p-channel MOSFETs 211 and 212 included in the input differential stage 201 of the op-amp 200 illustrated in FIG. 2, for example. The input differential stage 201 of the op-amp 200 illustrated in FIG. 2 operates at a voltage between a battery power supply and ground.

The op-amp 200 includes the input differential stage 201, a p-channel MOSFET 202, and an n-channel MOSFET 203. The input differential stage 201 includes the p-channel MOSFET 211 and the p-channel MOSFET 212.

The source terminal and a back-gate terminal of the p-channel MOSFET 202 are connected to the battery power supply. The drain terminal of the p-channel MOSFET 202 is connected to the source terminals of the p-channel MOSFET 211 and the p-channel MOSFET 212 included in the input differential stage 201. A signal bias is input to the gate terminal of the p-channel MOSFET. In the p-channel MOSFET 202, the back gate and the source are connected together, and therefore the back gate and the source have the same voltage. Thus, a p-channel MOSFET having a conventional structure may be used for the p-channel MOSFET 202.

Furthermore, in the p-channel MOSFET 211 and the p-channel MOSFET 212 included in the input differential stage 201, the source terminals, the drain terminals, and back-gate terminals are respectively connected to one another. The back-gate terminals of the p-channel MOSFET 211 and the p-channel MOSFET 212 are also connected to the battery power supply. Moreover, the source terminals of the p-channel MOSFET 211 and the p-channel MOSFET 212 are connected to the drain terminal of the p-channel MOSFET 202. In the p-channel MOSFET 211 and the p-channel MOSFET 212, the source terminals and the gate terminals have a low voltage of approximately greater than or equal to 10V and less than or equal to 20V, while the back-gate terminals are connected to the battery power supply and may therefore experience higher voltages. Therefore, lateral p-channel MOSFETs having the structure according to the present embodiment as described above are used for the p-channel MOSFET 211 and the p-channel MOSFET 212.

In addition, the source terminal and a back-gate terminal of the n-channel MOSFET 203 are grounded. The drain terminal of the n-channel MOSFET 203 is connected to the drain terminals of the p-channel MOSFET 211 and the p-channel MOSFET 212 included in the input differential stage 201. Similar to the gate terminal of the p-channel MOSFET 202, the signal bias is input to the gate terminal of the n-channel MOSFET 203. In the n-channel MOSFET 203, the back gate and the source are connected together, and therefore the back gate and the source have the same voltage. Thus, an n-channel MOSFET having a conventional structure may be used for the n-channel MOSFET 203.

Moreover, a vertical power MOSFET (not illustrated in the figure) is mounted on the same substrate as the op-amp 200.

### Embodiment 2

Next, an example of the structure of a lateral power MOSFET according to Embodiment 2 will be described with reference to FIGS. 3A and 3B. FIGS. 3A and 3B are explanatory drawings illustrating an example of the structure of the lateral power MOSFET according to Embodiment 2. FIG. 3A is a cross-sectional view of the structure of a lateral p-channel MOSFET 300. FIG. 3B is a plan view of the structure of the lateral p-channel MOSFET 300. FIG. 3A illustrates a cross section taken along line AA-AA′ in FIG. 3B.

The example of the structure according to Embodiment 2 as illustrated in FIGS. 3A and 3B is different from the example of the structure according to Embodiment 1 as illustrated in FIGS. 1A and 1B in that the p⁺ source diffusion region 6, the source-side p⁻ diffusion region 4, the source electrode 10, the gate electrode 8, and the LOCOS film 11 are formed symmetrically about the p⁺ drain diffusion region 5 in annular shapes centered on the p⁺ drain diffusion region 5 in a planar pattern.

Therefore, in Embodiment 2, the source-side p⁻ diffusion region 4 corresponds to the first diffusion region of the second conductivity type, and the drain-side p⁻ diffusion region 3 corresponds to the second diffusion region of the second conductivity type. Moreover, in Embodiment 2, the p⁺ source diffusion region 6 corresponds to the third diffusion region, and the p⁺ drain diffusion region 5 corresponds to the fourth diffusion region. The source-side p⁻ diffusion region 4 is formed along the periphery of the lateral p-channel MOSFET 300, and in order to provide electrical isolation between devices, the LOCOS film 11 is formed, on an area corresponding to the source-side p⁻ diffusion region 4 on the front surface of the semiconductor substrate 20, on a portion other than the p⁺ source diffusion region 6 that is positioned on the side opposite to the drain-side p⁻ diffusion region 3.

As illustrated in FIG. 3B, the drain electrode 9 extends in a straight line shape in a planar pattern. Moreover, the p⁺ drain diffusion region 5 and the drain-side p⁻ diffusion region 3 (not illustrated in the figure) are substantially quadrilateral in a planar pattern.

In the example of the structure according to Embodiment 2, voltage withstand structures may be formed in the regions surrounding the source such as the p⁺ source diffusion region 6 and the source-side p⁻ diffusion region 4.

Similar to in the example of the structure according to Embodiment 1 as illustrated in FIGS. 1A and 1B, in the example of the structure according to Embodiment 2 as illustrated in FIGS. 3A and 3B, the active channel region between the drain-side p⁻ diffusion region 3 and the source-side p⁻ diffusion region 4 has a closed planar shape in a planar pattern. Moreover, as illustrated by the dashed lines in FIG. 3B, the peripheral portions of the LOCOS film 11 are annular-shaped in a planar pattern. Therefore, when a low voltage is applied to the gate terminal 12 and the source terminal 14 and a high voltage is applied to the back-gate terminal 16, the location at which the electric field concentrates is distributed in an annular shape over the active channel region, and the electric field does not concentrate at the ends of the active channel region in the Y-axis direction as in the conventional technology illustrated in FIGS. 8A & 8B and 9A & 9B. In this way, similar to the example of the structure according to Embodiment 1 as illustrated in FIGS. 1A and 1B, the example of the structure according to Embodiment 2 as illustrated in FIGS. 3A and 3B makes it possible to improve the vertical withstand voltage of the lateral semiconductor device.

Moreover, similar to the p-channel MOSFET 100 illustrated in FIGS. 1A and 1B, the p-channel MOSFET 300 illustrated in FIGS. 3A and 3B may be used for the p-channel MOSFETs included in the input differential stage 201 of the op-amp 200 illustrated in FIG. 2.

### Embodiment 3

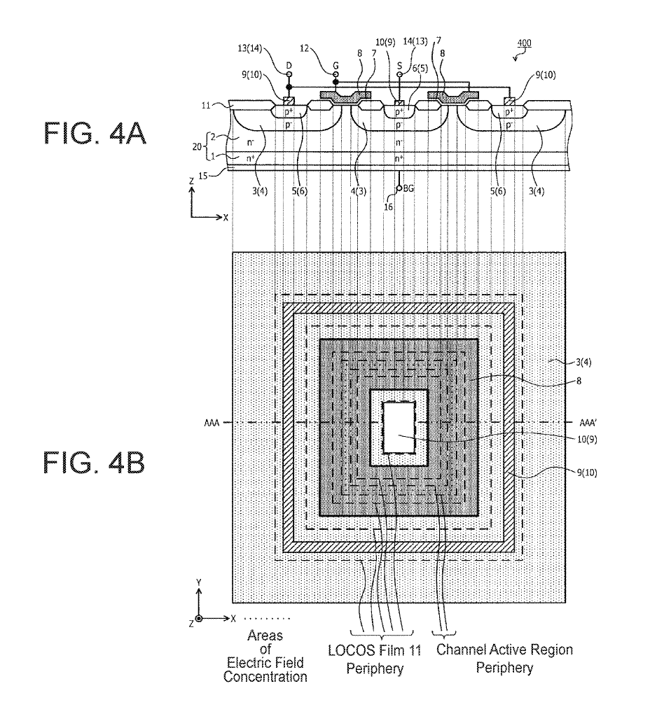

Next, an example of the structure of a lateral power MOSFET according to Embodiment 3 will be described with reference to FIGS. 4A and 4B. FIGS. 4A and 4B are explanatory drawings illustrating an example of the structure of the lateral power MOSFET according to Embodiment 3. FIG. 4A is a cross-sectional view of the structure of a lateral p-channel MOSFET 400. FIG. 4B is a plan view of the structure of the lateral p-channel MOSFET 400. FIG. 4A illustrates a cross section taken along line AAA-AAA′ in FIG. 4B.

The example of the structure according to Embodiment 3 as illustrated in FIGS. 4A and 4B is different from the example of the structure according to Embodiment 1 as illustrated in FIGS. 1A and 1B in that the LOCOS film 11 is also formed on the source-side p⁻ diffusion region 4 on the front surface of the semiconductor substrate 20, and the gate electrode 8, the gate insulating film 7, the drain-side p⁻ diffusion region 3, the p⁺ drain diffusion region 5, the drain electrode 8, and the LOCOS film 11 are formed symmetrically about and centered on the p⁺ source diffusion region 6. In Embodiment 3, the drain-side p⁻ diffusion region 3 corresponds to the first diffusion region of the second conductivity type, and the source-side p⁻ diffusion region 4 corresponds to the second diffusion region of the second conductivity type. Moreover, in Embodiment 3, the p⁺ drain diffusion region 5 corresponds to the third diffusion region, and the p⁺ source diffusion region 6 corresponds to the fourth diffusion region.

Furthermore, as illustrated in FIG. 4A, the LOCOS film 11 is formed on an area corresponding to the drain-side p⁻ diffusion region 3 on the front surface of the semiconductor substrate 20 on a first portion other than the p⁺ drain diffusion region 5 that is positioned on the p⁺ source diffusion region 6 side. Similar to in Embodiment 1, this LOCOS film 11 improves the lateral withstand voltage.

In addition, the LOCOS film 11 is also selectively formed on an area corresponding to the source-side p⁻ diffusion region 4 on the front surface of the semiconductor substrate 20 on a second portion other than the p⁺ source diffusion region 6 that is positioned on the p⁻ diffusion region 3 side. In the example illustrated in FIG. 4A, this LOCOS film 11 is formed sandwiching the p⁺ source diffusion region 6 in the area corresponding to the source-side p⁻ diffusion region 4 on the front surface of the semiconductor substrate 20.

The gate electrode 8 is formed extending from a section of the first portion to a section of the second portion on the front surface of the semiconductor substrate 20, with the gate insulating film 7 interposed therebetween. In other words, the gate electrode 8 and the gate insulating film 7 are formed extending onto the surfaces of both the drain-side p⁻ diffusion region 3 and the source-side p⁻ diffusion region 4, with portions of the gate electrode 8 and the gate insulating film 7 being formed covering portions of the LOCOS film 11.

Similar to in the structure according to Embodiment 1 as illustrated in FIGS. 1A and 1B, in the structure according to Embodiment 3 as illustrated in FIGS. 4A and 4B, when a low voltage is applied to the gate terminal 12 and the source terminal 14 and a high voltage is applied to the back-gate terminal 16, the active channel region takes a closed planar shape in a planar pattern. Moreover, as illustrated in FIG. 4B, the peripheral portions of the LOCOS film 11 are annular-shaped in a planar pattern. Furthermore, the peripheral portions of the LOCOS film 11 formed beneath the gate electrode 8 are disposed at positions separated from the active channel region. Therefore, unlike in conventional technologies, there are no locations in the active channel region that contact the edges of the LOCOS film 11, and the location at which the electric field concentrates is distributed in an annular shape (the location indicated by the dotted line in the active channel region in FIGS. 4A and 4B). In this way, similar to the structure according to Embodiment 1 as illustrated in FIGS. 1A and 1B, the structure according to Embodiment 3 as illustrated in FIGS. 4A and 4B makes it possible to improve the vertical withstand voltage. Moreover, in the p-channel MOSFET 400, the drain, the source, and the gate all have symmetric structures, thereby making it possible to reduce any potential variations in vertical withstand voltage resulting from variations that occur during manufacturing.

Similar to in Embodiment 2, the positional relationship between the source and the drain may be reversed in the p-channel MOSFET 400 illustrated in FIGS. 4A and 4B. Here, reversing the positional relationship between the source and the drain refers to forming the drain electrode 9 at the center and forming the source electrode 10 on the side of the gate electrode 8 opposite to the drain electrode 9. When the positional relationship between the source and the drain is reversed, the source-side p⁻ diffusion region 4 corresponds to the first diffusion region of the second conductivity type, and the drain-side p⁻ diffusion region 3 corresponds to the second diffusion region of the second conductivity type. Moreover, the p⁺ source diffusion region 6 corresponds to the third diffusion region, and the p⁺ drain diffusion region 5 corresponds to the fourth diffusion region. In FIGS. 4A and 4B, the reference characters enclosed in parentheses are the reference characters corresponding to the case in which the drain electrode 9 is formed at the center. Reference characters that do not have these alternative parenthetical reference characters appended thereto indicate that the corresponding component is the same regardless of whether the drain electrode 9 is at the center or the source electrode 10 is at the center. When the drain electrode 9 is at the center of the p-channel MOSFET 400, the gate, the source, and the drain are formed symmetrically in the X-axis direction and the Y-axis direction about the drain electrode 9 at the center.

Similar to the p-channel MOSFETs 100 and 300 illustrated in FIGS. 1A & 1B and FIGS. 3A & 3B, the p-channel MOSFET 400 illustrated in FIGS. 4A and 4B may be used for the p-channel MOSFETs 211 and 212 included in the input differential stage 201 of the op-amp 200 illustrated in FIG. 2. Moreover, using the p-channel MOSFET 400 illustrated in FIGS. 4A and 4B for the p-channel MOSFET 211 and the p-channel MOSFET 212 included in the input differential stage 201 illustrated in FIG. 2 is even more effective. The matching properties of the p-channel MOSFET 211 and the p-channel MOSFET 212 play a critical role in improving the overall circuit performance of the op-amp 200. Here, “matching properties” refers to the relative precision in performance from one device to the next and provides an indication of to what extent the p-channel MOSFET 211 and the p-channel MOSFET 212 differ from one another in terms of performance. When the p-channel MOSFET 211 and the p-channel MOSFET 212 used in the input differential stage exhibit poor matching properties, the differences in performance between the two MOSFETs 211 and 212 increase the offset voltage of the op-amp 200, thereby resulting in poorer overall circuit performance. One well-known method of improving matching between the two p-channel MOSFETs 211 and 212 involves arranging a plurality of the p-channel MOSFETs 211 and 212 in a symmetric manner (in a common-centroid layout, for example) in order to reduce the effects of factors such as dimensional errors due to manufacturing variations. The p-channel MOSFET 400 is thus advantageous in terms of offering excellent layout symmetry due to the source, drain, and gate all having symmetric structures and can therefore be effectively used in the input differential stage 201.

### Embodiment 4

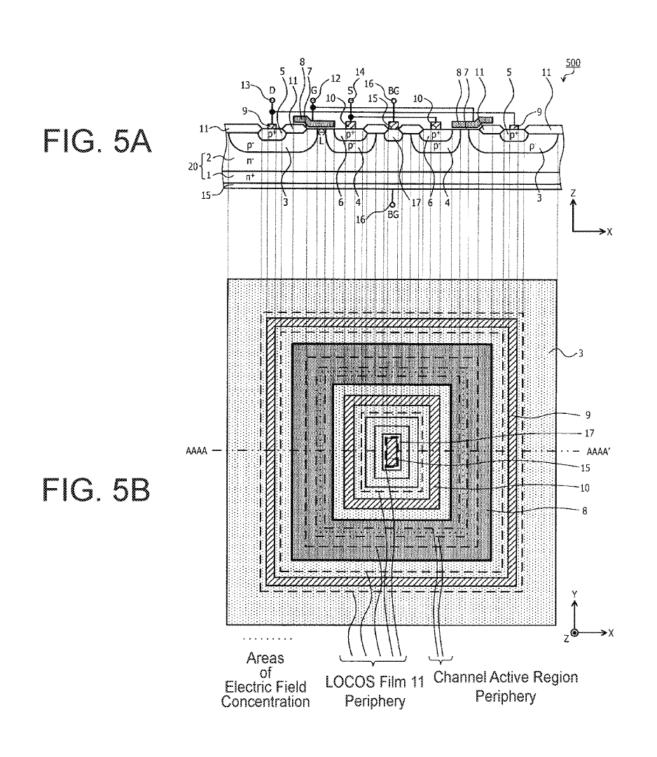

Next, an example of the structure of a lateral power MOSFET according to Embodiment 4 will be described with reference to FIGS. 5A and 5B. FIGS. 5A and 5B are explanatory drawings illustrating an example of the structure of the lateral power MOSFET according to Embodiment 4. FIG. 5A is a cross-sectional view of the structure of a lateral p-channel MOSFET 500. FIG. 5B is a plan view of the structure of the lateral p-channel MOSFET 500. FIG. 5A illustrates a cross section taken along line AAAA-AAAA′ in FIG. 5B.

The example of the structure according to Embodiment 4 as illustrated in FIGS. 5A and 5B is different from the example of the structure according to Embodiment 1 as illustrated in FIGS. 1A and 1B in the following two respects. First, as illustrated in FIG. 5A, the back-gate electrode 15 is also formed on the front surface of the semiconductor substrate 20. Here, an n⁺ back-gate diffusion region 17 is formed in the front surface of the semiconductor substrate 20 so that the back-gate electrode 15 can then be formed on the front surface thereof.

Second, the gate electrode 8, the gate insulating film 7, the p⁺ source diffusion region 6, the source-side p⁻ diffusion region 4, the source electrode 10, the p⁺ drain diffusion region 5, the drain-side p⁻ diffusion region 3, and the drain electrode 9 are formed surrounding the n⁺ back-gate diffusion region 17 in symmetric shapes that are centered on the n⁺ back-gate diffusion region 17.

In Embodiment 4, the drain-side p⁻ diffusion region 3 corresponds to the first diffusion region of the second conductivity type, and the source-side p⁻ diffusion region 4 corresponds to the second diffusion region of the second conductivity type. Moreover, in Embodiment 4, the p⁺ drain diffusion region 5 corresponds to a third diffusion region of the second conductivity type, and the p⁺ source diffusion region 6 corresponds to a fourth diffusion region of the second conductivity type. The n⁺ back-gate diffusion region 17 corresponds to a fifth diffusion region of the first conductivity type. Moreover, in order to electrically isolate the source and the back gate from one another, the LOCOS film 11 is also formed on the portion of the front surface of the semiconductor substrate 20 that is positioned between the n⁺ back-gate diffusion region 17 and the p⁺ source diffusion region 6.

As illustrated in FIG. 5B, the back-gate electrode 15 extends in a straight line shape in a planar pattern. Moreover, the n⁺ back-gate diffusion region 17 is substantially quadrilateral in a planar pattern. Furthermore, the source electrode 10, the p⁺ source diffusion region 6 (not illustrated in the figure), and the source-side p⁻ diffusion region 4 (not illustrated in the figure) have closed planar shapes and are arranged surrounding the back-gate electrode 15 and the n⁺ back-gate diffusion region 17 in a planar pattern. In addition, the gate electrode 8 and the gate insulating film 7 (not illustrated in the figure) have closed planar shapes and are arranged surrounding the source electrode 10 and the p⁺ source diffusion region 6 in a planar pattern. Moreover, the drain electrode 9, the p⁺ drain diffusion region 5 (not illustrated in the figure), and the drain-side p⁻ diffusion region 3 (not illustrated in the figure) have closed planar shapes in a planar pattern, and the drain-side p⁻ diffusion region 3 is arranged surrounding the source-side p⁻ diffusion region 4 (not illustrated in the figure). The drain electrode 9 and the p⁺ drain diffusion region 5 are arranged surrounding the gate electrode 8.

Similar to in the example of the structure according to Embodiment 1 as illustrated in FIGS. 1A and 1B, in the example of the structure according to Embodiment 4 as illustrated in FIGS. 5A and 5B, the active channel region sandwiched between the drain-side p⁻ diffusion region 3 and the source-side p⁻ diffusion region 4 has a closed planar shape in a planar pattern. Moreover, the peripheral portions of the LOCOS film 11 are annular-shaped in a planar pattern. Furthermore, the peripheral portion of the LOCOS film 11 formed beneath the gate electrode 8 is disposed at a position separated from the active channel region. Therefore, the location at which the electric field concentrates in the active channel region has an annular shape, as indicated by the dotted line in the active channel region. Thus, when a low voltage is applied to the gate terminal 12 and the source terminal 14 and a high voltage is applied to the back-gate terminal 16, the resulting electric field is distributed over the entire active channel region, and the electric field does not concentrate at the ends of the active channel region in the Y-axis direction as in the conventional technology illustrated in FIGS. 8A & 8B and 9A & 9B. This makes it possible to improve the vertical withstand voltage of the lateral semiconductor device. Moreover, the p-channel MOSFET 500 having the example of the structure according to Embodiment 4 can be applied to a p-channel MOSFET in which the same voltage is applied to the back-gate terminal and the source terminal. Furthermore, all of the devices used for the p-channel MOSFET have the same structure, thereby making it possible to reduce variations in performance between the devices.

In addition, the back-gate terminal 16 is formed on the front surface of the semiconductor substrate 20, which makes it easy to connect the back-gate terminal 16 to other devices formed on the semiconductor substrate 20 or to other circuits that are not formed on the semiconductor substrate 20, for example.

Moreover, similar to in Embodiment 2, in Embodiment 4 the positions of the source and the drain may be reversed. More specifically, although in the example illustrated in FIGS. 5A and 5B the p⁺ drain diffusion region 5 and the p⁻ diffusion region 3 are formed in annular shapes surrounding the p⁺ source diffusion region 6 and the p⁻ diffusion region 4, the p⁺ source diffusion region 6 and the p⁻ diffusion region 4 may be formed in annular shapes surrounding the p⁺ drain diffusion region 5 and the p⁻ diffusion region 3, similar to in Embodiment 2.

Furthermore, similar to in Embodiment 3, in Embodiment 4 the gate electrode 8 may be formed such that an edge portion thereof is positioned above a LOCOS film 11 that is formed on the surface of the p⁻ diffusion region 4. More specifically, the LOCOS film 11 may also be formed, on an area corresponding to the p⁻ diffusion region 4 on the front surface of the semiconductor substrate 20, on a portion other than the source diffusion region 6 that is positioned on the p⁻ diffusion region side of the drain side, and the gate electrode 8 may be formed above this LOCOS film 11 that is formed on the surface of the p⁻ diffusion region 4.

In addition, although the back-gate terminal 16 was formed on the rear surface of the semiconductor substrate 20 in the p-channel MOSFETs according to Embodiments 1 to 3, the present invention is not limited to these examples, and the back-gate terminal 16 may also be formed on the front surface of the semiconductor substrate 20 as in the structure according to Embodiment 4. When the back-gate terminal 16 is formed on the front surface of the semiconductor substrate 20 in the p-channel MOSFETs according to Embodiments 1 to 3, the back-gate terminal 16 and an n⁺ back-gate diffusion region 17 are formed on a portion of the front surface of the semiconductor substrate 20 that is positioned near the terminal portion of the p-channel MOSFET and separated from the source and the drain, for example. Moreover, the LOCOS film 11 is formed so as to provide electrical isolation between the back gate and the source, the drain, and the gate.

(Semiconductor Device)

Next, an example of a semiconductor device according to an embodiment in which a lateral semiconductor device and a vertical semiconductor device are formed on the same substrate will be described with reference to FIG. 6.

FIG. 6 is a cross-sectional view illustrating the structure of the semiconductor device according to the present embodiment. Here, a semiconductor device 600 includes the lateral p-channel MOSFET 100 as the lateral semiconductor device as well as a vertical n-channel trench gate MOSFET 601 as a vertical power semiconductor device for an output stage. The lateral p-channel MOSFET 100 controls and protects the n-channel MOSFET 601.

Although here the p-channel MOSFET 100 having the example of the structure according to Embodiment 1 and illustrated in FIGS. 1A and 1B is used as the lateral semiconductor device included in the semiconductor device 600 as an example, the semiconductor device is not limited to this example and may include the p-channel MOSFET having one of the other example structures described above. Moreover, in the n-channel trench gate MOSFET 601, current flows from the rear surface side of the semiconductor substrate 20 towards the front surface of the semiconductor substrate 20.

As illustrated in FIG. 6, the back-gate electrode 15 and the back-gate terminal 16 of the lateral p-channel MOSFET 100 also function as a drain electrode 40 and a drain terminal 41 of the n-channel MOSFET 601. Applications for a semiconductor device such as that illustrated in FIG. 6 include sophisticated power semiconductor devices that have both a high-side switching feature and op-amp functionality, for example.

In the semiconductor device 600, to operate the lateral p-channel MOSFET 100, a high voltage is applied to the back-gate terminal 16 of the lateral p-channel MOSFET 100 while a low voltage is applied to the source terminal 14, and therefore the voltage between the source and the back gate increases.

The n-channel MOSFET 601 is a trench-gate metal-oxide-semiconductor insulated gate (MOS gate) structure that includes a trench 35, a gate insulating film 36, a gate electrode 37, a p⁻ base region 31, an n⁺ source region 34, a p⁺ diffusion region 33, and a drain-side p⁻ diffusion region 32, for example.

The drain-side p⁻ diffusion region 32 is selectively formed in the surface layer on the front surface side of the semiconductor substrate 20 at a position that is separated from the drain-side p⁻ diffusion region 3 of the lateral p-channel MOSFET 100. Moreover, the p⁻ base region 31 is selectively formed in the surface layer on the front surface side of the semiconductor substrate 20 at a position that is separated from the drain-side p⁻ diffusion region 32. The p⁺ diffusion region 33 is selectively formed within the p⁻ base region 31. Here, the impurity concentration of the p⁺ diffusion region 33 is greater than those of the drain-side p⁻ diffusion region 32 and the p⁻ base region 31.

The n⁺ source region 34 is selectively formed, sandwiching the p⁺ diffusion region 33, within the p⁻ base region 31.

The trench 35 contacts the n⁺ source region 34, the p⁻ base region 31, and an epitaxial layer 2 in the Z-axis direction. Moreover, the trench 35 is formed sandwiching the n⁺ source region 34 and the p⁻ base region 31 in the X-axis direction. The gate electrode 37 is formed inside the trench 35 with the gate insulating film 36 interposed therebetween. Voltages are applied to the gate electrode 37 via a gate terminal 38.

The n⁺ source region 34 and the p⁺ diffusion region 33 contact a source electrode (a front surface electrode; not illustrated in the figure). Voltages are applied to the n⁺ source region 34 and the p⁺ diffusion region 33 via a source terminal 39.

FIG. 7 is an explanatory drawing illustrating the relationship between channel length L and vertical withstand voltage in a semiconductor device according to the present embodiment and in a conventional semiconductor device. In the graph 700, the vertical axis represents the vertical withstand voltage of the p-channel MOSFET, and the horizontal axis represents the channel length L. This graphs shows to what extent the vertical withstand voltage decreases as the channel length is increased, where the vertical withstand voltage is 100% at a reference channel length L.

Here, the curvature of the edges of the source-side p⁻ diffusion region and the drain-side p⁻ diffusion region decreases the vertical withstand voltage. As the channel length L is increased, the curvature of the edges of the source-side p⁻ diffusion region and the drain-side p⁻ diffusion region further decreases the planarity of the vertical p-n junction (that is, the p-n junction between the drift region and the source-side p⁻ diffusion region and drain-side p⁻ diffusion region), thereby decreasing the vertical withstand voltage. Conversely, when the channel length L is decreased, the planarity of the vertical p-n junction approaches that of an ideal planar p-n junction, thereby increasing the vertical withstand voltage.

Furthermore, as illustrated in FIG. 7, in both the conventional semiconductor device and the semiconductor device according to the present embodiment, as the channel length is increased, the vertical withstand voltage decreases to a prescribed percentage and then remains equal to the same withstand voltage after reaching that prescribed percentage. However, the amount by which the vertical withstand voltage decreases in the conventional semiconductor device is greater than the amount by which the vertical withstand voltage decreases in the semiconductor device according to the present embodiment. Therefore, the semiconductor device according to the present embodiment makes it possible to improve the vertical withstand voltage of the lateral semiconductor device in comparison to in conventional semiconductor devices.

In the lateral MOSFET of the semiconductor device according to the present embodiment as described above, the drain-side diffusion region, the drain diffusion region, the gate insulating film, the gate electrode, and the LOCOS film are formed in annular shapes surrounding the source diffusion region. Therefore, the active channel region between the drain diffusion region and the source diffusion region as well as the edges of the LOCOS film are also annular-shaped. Thus, when a low voltage is applied to the source terminal and the gate terminal and a high voltage is applied to the back-gate terminal, the resulting electric field is distributed in an annular shape over the active channel region, thereby making it possible to improve the vertical withstand voltage.

Alternatively, in the lateral MOSFET of the semiconductor device according to the present embodiment, the source-side diffusion region, the source diffusion region, the gate insulating film, the gate electrode, and the LOCOS film are formed in annular shapes that are centered on the drain diffusion region. Therefore, the active channel region between the drain diffusion region and the source diffusion region as well as the edges of the LOCOS film are also annular-shaped. Thus, when a low voltage is applied to the source terminal and the gate terminal and a high voltage is applied to the back-gate terminal, the resulting electric field is distributed in an annular shape over the active channel region, thereby making it possible to improve the vertical withstand voltage.

Alternatively, in the lateral MOSFET of the semiconductor device according to the present embodiment, the source-side diffusion region, the source diffusion region, the drain-side diffusion region, the drain diffusion region, the gate insulating film, the gate electrode, the drain electrode, and the LOCOS film are formed in annular shapes that are centered on the back-gate electrode formed on the front surface of the semiconductor substrate. Therefore, the active channel region between the drain diffusion region and the source diffusion region as well as the edges of the LOCOS film are also annular-shaped. Thus, when a low voltage is applied to the source terminal and the gate terminal and a high voltage is applied to the back-gate terminal, the resulting electric field is distributed in an annular shape over the active channel region, thereby making it possible to improve the vertical withstand voltage.

Furthermore, in the p-channel MOSFETs according to embodiments of the present invention, the annular-shaped structures are not limited to being quadrilateral in shape and may alternatively be circular or running track-shaped.

In addition, the p-channel MOSFET according to embodiments of the present invention is not limited to being a p-channel MOSFET that is formed on the same semiconductor substrate as a vertical power semiconductor device as described above and may be used for any p-channel MOSFET included in a circuit in which a high voltage in applied to the back-gate and a low voltage is applied to the source.

Moreover, although the semiconductor device according to embodiments of the present embodiment was described as being a p-channel MOSFET as an example, the semiconductor device is not limited to this example and may alternatively be an n-channel MOSFET.

### INDUSTRIAL APPLICABILITY

As described above, the semiconductor device according to the present invention is suitable for use in devices that include an op-amp, for example. More specifically, the semiconductor device according to the present invention is suitable for use in sophisticated power semiconductor devices that include a high-side switch and an op-amp, for example.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device having a lateral semiconductor device and a vertical semiconductor device formed on a semiconductor substrate of a first conductivity type,
wherein the lateral semiconductor device comprises:
a first diffusion region of a second conductivity type selectively formed in a surface layer of one principal surface of the semiconductor substrate;
a second diffusion region of the second conductivity type selectively formed separated from the first diffusion region in the surface layer of the one principal surface of the semiconductor substrate;
a third diffusion region of the second conductivity type selectively formed within the first diffusion region and at a higher impurity concentration than the first diffusion region;
a fourth diffusion region of the second conductivity type selectively formed within the second diffusion region and at a higher impurity concentration than the second diffusion region;
a local insulating film selectively formed around a periphery of the lateral semiconductor device on the one principal surface of the semiconductor substrate, and also selectively formed on a portion of the one principal surface of the semiconductor substrate positioned between the third diffusion region and the fourth diffusion region; and
a gate electrode formed on at least a portion of the one principal surface of the semiconductor substrate positioned between the first diffusion region and the second diffusion region, with a gate insulating film interposed therebetween, the gate electrode also being formed on a portion of a surface of the local insulating film with the gate insulating film interposed therebetween,
wherein the semiconductor device is configured to receive a voltage on another principal surface of the semiconductor substrate that is set to be higher than voltages of the gate electrode, the third diffusion region, and the fourth diffusion region by greater than or equal to a prescribed value, and
wherein the first diffusion region, the third diffusion region, the gate electrode, and the local insulating film are formed in annular shapes surrounding the fourth diffusion region in a planar pattern.

2. The semiconductor device according to claim 1,
wherein the third diffusion region is a drain diffusion region,
wherein the fourth diffusion region is a source diffusion region, and
wherein, on the portion of the one principal surface of the semiconductor substrate positioned between the third diffusion region and the fourth diffusion region, the local insulating film is selectively formed on a portion of the first diffusion region other than where the third diffusion region is formed.

3. The semiconductor device according to claim 1,
wherein the third diffusion region is a source diffusion region,
wherein the fourth diffusion region is a drain diffusion region, and
wherein, on the portion of the one principal surface of the semiconductor substrate positioned between the third diffusion region and the fourth diffusion region, the local insulating film is selectively formed on a portion of the second diffusion region other than where the fourth diffusion region is formed.

4. The semiconductor device according to claim 1,
wherein, on the portion of the one principal surface of the semiconductor substrate positioned between the third diffusion region and the fourth diffusion region, the local insulating film is selectively formed on a portion of the first diffusion region other than where the third diffusion region is formed, and is also selectively formed on a portion of the second diffusion region other than where the fourth diffusion region is formed,
wherein the gate electrode is formed to cover at least a portion of a surface of the local insulating film that is selectively formed on the portion of the first diffusion region and a portion of a surface of the local insulating film that is selectively formed on the portion of the second diffusion region, and
wherein the third diffusion region, the gate electrode, and the local insulating film are formed symmetrically about the fourth diffusion region in a planar pattern.

5. The semiconductor device according to claim 2,
wherein the lateral semiconductor device further includes:
a fifth diffusion region of the first conductivity type selectively formed in the surface layer of the one principal surface of the semiconductor substrate, the fifth diffusion region being separated from the first diffusion region and the second diffusion region; and
a back-gate electrode contacting the fifth diffusion region, and
wherein the second diffusion region and the fourth diffusion region are formed in annular shapes surrounding the fifth diffusion region in a planar pattern.

6. The semiconductor device according to claim 1,
wherein the first conductivity type is n-type, and
wherein the second conductivity type is p-type.

7. The semiconductor device according to claim 1, wherein the prescribed value is greater than or equal to 40V.

8. An operation amplifier, comprising
an input differential stage;
a p-channel MOSFET connected to the input differential stage; and
an n-channel MOSFET connected to the input differential stage, wherein the input differential stage includes a lateral p-type MOSFET device that comprises:
a first diffusion region of p-type selectively formed in a surface layer of one principal surface of a semiconductor substrate of n-type;
a second diffusion region of p-type selectively formed separated from the first diffusion region in the surface layer of the one principal surface of the semiconductor substrate;
a third diffusion region of p-type selectively formed within the first diffusion region and at a higher impurity concentration than the first diffusion region;
a fourth diffusion region of p-type selectively formed within the second diffusion region and at a higher impurity concentration than the second diffusion region;
a local insulating film selectively formed around a periphery of the lateral semiconductor device on the one principal surface of the semiconductor substrate, and also selectively formed on a portion of the one principal surface of the semiconductor substrate positioned between the third diffusion region and the fourth diffusion region; and
a gate electrode formed on at least a portion of the one principal surface of the semiconductor substrate positioned between the first diffusion region and the second diffusion region, with a gate insulating film interposed therebetween, the gate electrode also being formed on a portion of a surface of the local insulating film with the gate insulating film interposed therebetween,
wherein the operational amplifier is configured such that another principal surface of the semiconductor substrate of the lateral p-type MOSFET device receives a voltage that is set to be higher than voltages of the gate electrode, the third diffusion region, and the fourth diffusion region by greater than or equal to a prescribed value, and
wherein the first diffusion region, the third diffusion region, the gate electrode, and the local insulating film are formed in annular shapes surrounding the fourth diffusion region in a planar pattern.

9. The semiconductor device according to claim 4,
wherein the third diffusion region is a drain diffusion region, and
wherein the fourth diffusion region is a source diffusion region.
